(19) United States
(12) Patent Application Publication
(10) Pub. No.: US 2006/0127820 A1
(43) Pub. Date: Jun. 15, 2006

(54) METHOD FOR FORMING PHOTORESIST PATTERN AND METHOD FOR TRIMING PHOTORESIST PATTERN

(76) Inventors: Calvin Wu, Tainan County (TW); Sheng-Yueh Chang, Taipei County (TW); Jay Hwang, Hsinchu City (TW)

Correspondence Address: JIANQ CHYUN INTELLECTUAL PROPERTY OFFICE, 7 FLOOR-1, NO. 100, ROOSEVELT ROAD, SECTION 2, TAIPEI, 100, TW

(21) Appl. No.: 11/162,161

(22) Filed: Aug. 31, 2005

(30) Foreign Application Priority Data
Dec. 13, 2004 (TW) 93138539

(51) Int. Cl. G03F 7/00

(52) U.S. Cl. 430/322; 430/325

(57) ABSTRACT

A method for forming a photoresist pattern is described. A photoresist layer is first formed over a substrate, and then an exposure process and a development process are performed to pattern the photoresist layer so as to form a patterned photoresist layer. Next, a multiple-trimming process is performed to trim the patterned photoresist lay to form a photoresist pattern. The multiple-trimming process includes at least one step of alkaline solution treatment and/or at least one step of neutral solution treatment. The method is applicable for improving properties of smoothness of the surface, and uniformity and minification of critical dimensions of the photoresist patterns.

### CROSS-REFERENCE TO RELATED APPLICATION

This application claims the priority benefit of Taiwan application serial no. 93138539, filed on Dec. 13, 2004. All disclosure of the Taiwan application is incorporated herein by reference.

### BACKGROUND OF THE INVENTION

1. Field of the Invention

The present invention generally relates to a photolithographic process, and more particularly to a method of forming a photoresist pattern and a method of trimming a photoresist pattern.

2. Description of the Related Art

When the extent of integration of integrated circuits in electronic devices becomes ever-increased, the sizes of the entire electronic devices are getting smaller. Photolithography is an essential step during fabricating processes of semiconductor devices. In metal-oxide-semiconductor (MOS) devices, for instance, structural elements, such as patterns of various layers and regions with dopants, are all defined through a photolithographic process. The photolithographic process includes three essential steps: coating, exposure and development.

The entire photolithographic process can also be further divided into steps of dehydration, priming, coating, soft baking, exposure, post-exposure baking, development, and hard baking. The major purpose of the exposure step is to let the photoresist layer that covers on the surface of a chip to absorb an appropriate amount of energy for photochemical transformation. After steps of exposure and post-exposure baking, a development step can be carried out on a photoresist layer to clean away portions of the photoresist layer covering on the surface of the chip through a chemical neutralization reaction, so as to form a photoresist pattern.

FIGS. 1A to 1C are cross-sectional views illustrating a conventional method for forming a photoresist pattern. As shown in FIG. 1A, a material layer 102 is formed on a substrate 100, and a photoresist layer 104 is further formed on the material layer 102.

Next, referring to FIG. 1B, a mask 106 is set above the photoresist layer 104, wherein the mask 106 has a transparent region 106a and a non-transparent region 106b. An exposure step 108 is then performed on the photoresist layer 104 through the mask 106 to form an exposed region 104a and an unexposed region 104b in the photoresist layer 104. In the exposed region 104a, photochemical reactions occurred due to illumination of the light.

Further, referring to FIG. 1C, an exposure step is performed on the photoresist layer 104 to remove the exposed region 104a of the photoresist layer 104. The unexposed region remains to form a patterned photoresist layer 105.

The following problems, however, present in the above process for forming the patterned photoresist layer 105. With the miniaturization of electronic devices, the preciseness and uniformity of critical dimensions become more difficult to be controlled during a photolithographic process. In addition, during the exposure process 108, the light unabsorbed by the photoresist layer will reflect and interfere with the incident light, which will cause uneven exposure of the photoresist layer 104, and thus after the development step, result an uneven profile and rough surfaces of the patterned photoresist layer 105. Moreover, when the exposure light beam is projected through the pattern of the mask 106 into the photoresist layer 104, the light beam will be diffused due to scattering effect, and on the other hand, interference will occur to cause multiple exposures and affect the extend of actual exposure of the photoresist layer 104. Thus, the preciseness of the critical dimensions of the patterns will be decreased.

In addition, the surface of the mask 106, after a long period use, will be contaminated with particles generated in the process, and during the exposure step, the pattern transferred onto the photoresist layer 104 will have a poor resolution. As a result, the resulting patterned photoresist layer 105 will have an uneven profile and rough surfaces. These phenomena have adversary effects that the critical dimensions cannot be effectively controlled, the after-etching inspection will have deviations, and the patterns cannot be obtained correctly.

Moreover, during the developing process, the exposed region of the photoresist layer has to be removed by using a developer, while the unexposed region of the photoresist layer may be eroded by the developer. The erosion will cause the profile of the photoresist layer becoming uneven and thus affect the preciseness and uniformity of the critical dimensions.

### SUMMARY OF THE INVENTION

Accordingly, the present invention is to provide a method for forming a photoresist pattern so as to improve the smoothness of the profile of the patterned photoresist layer, and thus to make the pattern of the photoresist layer more precise.

The present invention is also to provide a method for multiply trimming the photoresist pattern so as to enable the critical dimensions of the photoresist pattern to be minimized and thus to enhance the uniformity of the critical dimensions.

According to an embodiment of the invention, a method for forming a photoresist pattern is provided. A photoresist layer is formed over a substrate and an exposure process is carried out upon the photoresist layer. A development process is then performed to form a patterned photoresist layer. Next, a multiple-trimming process is performed to the patterned photoresist layer, wherein the multiple-trimming process includes at least one step of alkaline solution treatment and/or at least one step of neutral solution treatment.

According to another embodiment of the invention, a method for trimming a patter of the patterned photoresist layer is provided. The trimming method includes performing a multiple-trimming process upon the patterned photoresist layer. Wherein, the multiple-trimming process includes at least one step of alkaline solution treatment and/or at least one step of neutral solution treatment.

Through the methods of this invention, the photoresist pattern can have a relatively even profile and smooth surfaces. Further, the critical dimensions can be controlled more precisely and with enhanced uniformity.

It is to be understood that both the foregoing general description and the following detailed description are exemplary, and are intended to provide further explanation of the invention as claimed.

### BRIEF DESCRIPTION OF THE DRAWINGS

FIGS. 1A to 1C are cross-sectional views showing a conventional method for forming a photoresist pattern.

FIGS. 2A to 2D are cross-sectional views showing the method for forming the photoresist pattern and the method for trimming the photoresist pattern according to a preferred embodiment of the present invention.

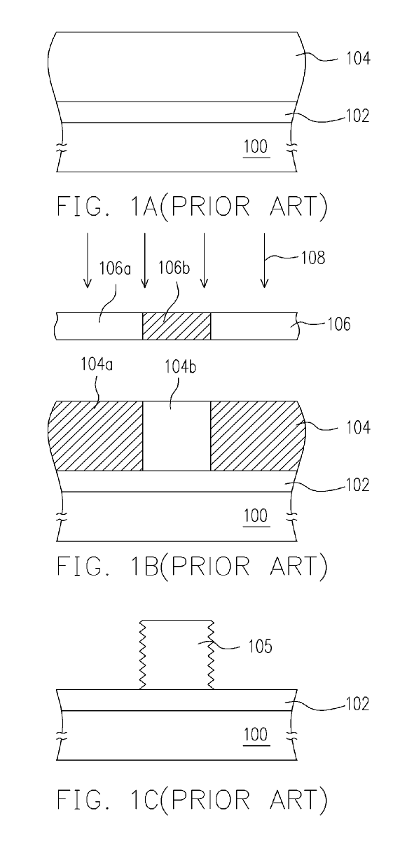

### DESCRIPTION OF THE PREFERRED EMBODIMENTS

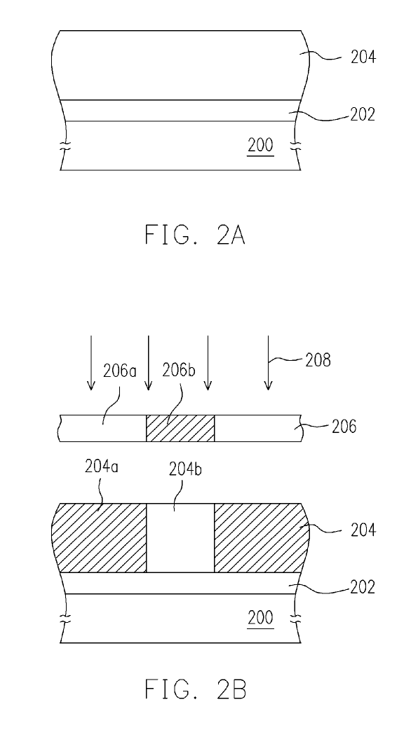

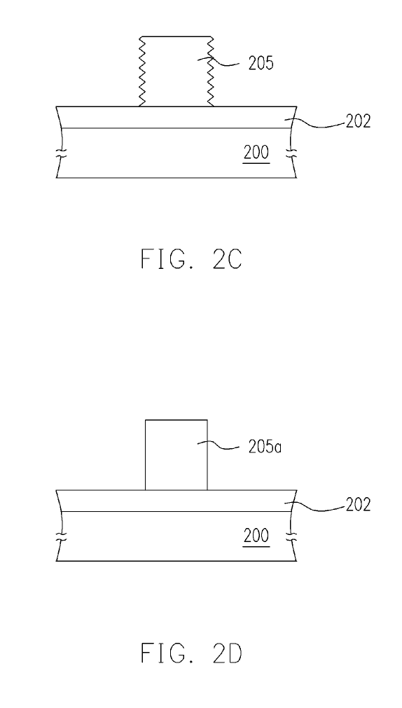

A method for forming a photoresist pattern including a method for trimming a pattern of a patterned photoresist layer according to this invention is shown in FIGS. 2A to 2D. Referring to 2A, a material layer 202 is formed over the substrate 200, while the material layer 202 can be a conductive or non-conductive layer. Wherein, the conductive layer is made of, for example, metal or polycrystalline silicon, while the non-conductive layer is made of, for example, silicon nitride, silicon oxide, or other dielectric material. A photoresist layer 204 is then formed over the material layer 202, wherein the photoresist layer 204 is made of, for example, a sensitive material as a mixture of a resin, sensitizer and solvent. The photoresist layer 204 is formed via a process including the steps of, for example, performing spin coating the sensitive material on the material layer 202, and then performing soft baking to remove the solvent in the sensitive material and to make the sensitive material, originally as liquid, to become the solidified photoresist layer.

Next, referring to FIG. 2B, a mask 206 is set above the photoresist layer 204, wherein the mask 206 has a transparent region 206a and a non-transparent region 206b. An exposure process 208 is carried out on the photoresist layer 204, wherein the light source for the exposure process 208 is, for example, i-line, krypton-fluoride laser, argon-flouride laser, or other light source. Thus, an exposed region 204a and an unexposed region 204b are formed in the photoresist layer 204, wherein photochemical reactions will occur in the exposed region 204a under illumination of the light source.

Next, referring to FIG. 2C, a developing process is performed. After being exposed, for example, the photoresist layer 204 is immersed in a developer for removing the exposed region 204a but keeping the unexposed region 204b to form a patterned photoresist layer 205. Wherein, the developer is, for example, an alkaline solution that contains an organic alkali.

As shown in FIG. 2C, the patterned photoresist layer 205 formed through the foregoing-mentioned exposure and development processes will have a rough contour. The critical dimensions of the patterned photoresist layer 205 may not be precisely controlled. In addition, the critical dimensions may not have desirable uniformity. After the foregoing-mentioned exposure and development processes, therefore, the present invention further includes a multiple-trimming process, as shown in 2D, to form a photoresist pattern 205a. The multiple-trimming process includes at least one step of alkaline solution treatment and/or at least one step of neutral solution treatment. In an embodiment, the alkaline solution used in the alkaline solution treatment includes, for example, an organic alkali. The alkaline solution has a pH value lower than that of the developer used in the development process, which is preferably between 8 and 14, for example. The neutral solution used in the neutral solution treatment is, for example, water, a surfactant, or a mixture thereof. Wherein, the surfactant in the neutral solution is, for example, acetylene diol having a pH of greater than 5.

More specifically, in the alkaline solution treatment, the substrate 200 having the material layer 202 and the patterned photoresist layer 205 thereon is immersed in a container filled with an alkaline solution. The alkaline solution is capable of smoothing the rough contour of the patterned photoresist layer 205 to form the photoresist pattern 205a shown in FIG. 2D. Similarly, in the neutral solution treatment, the substrate 200 having the material layer 202 and the patterned photoresist layer 205 thereon is immersed in a container filled with a neutral solution. The neutral solution is capable of smoothing the rough contour of the patterned photoresist layer 205 to form the photoresist pattern 205a shown in FIG. 2D.

In the foregoing embodiment of this invention, the multiple-trimming process can be carried out through two consecutive steps treated by the same solution (e.g., an alkaline solution or a neutral solution), or through two consecutive steps treated by different solutions (e.g., an alkaline solution and than a neutral solution, or vise versa). The multiple-trimming process can be also carried out through multiple treatments of a neutral solution and multiple treatments of an alkaline solution, alternately, until smoothness of the contour of the photoresist pattern and the preciseness and the uniformity of the critical dimensions become desirable.

In addition, during the multiple-trimming process, a heating treatment can be conducted such that a solution used in the multiple-trimming process causes a chain reaction. The heating treatment is usually conducted at about 90-150° C., preferably at about 110-130° C., to assist the multiple-trimming process.

In the foregoing embodiment as shown in FIGS. 2A to 2D, the photoresist layer 204 is described as a positive photoresist layer. This however should not be construed as a limitation upon the scope of the invention. Rather, the present invention is also applicable to photolithographic process of a negative photoresist layer. In other words, this invention also provides a multiple-trimming process on a negative photoresist layer to improve the smoothness of the profile of the photoresist pattern and to control the preciseness and uniformity of the critical dimensions.

After the step shown in FIG. 2D, the photoresist pattern 205a can be used as an etching mask or ion-implanting mask in order to performing an etching step or a ion implantation step in the material layer 202 that is under the photoresist pattern 205a.

In conclusion, the present invention provides a method for forming a photoresist pattern including a multiple-trimming process. Through treatments of an alkaline solution and/or a neutral solution, the pattern of a patterned photoresist layer is trimmed for decreasing the roughness of the contour of the pattern. In addition, the trimming process is useful to increase preciseness and uniformity of critical dimensions of the photoresist pattern.

It will be apparent to those skilled in the art that various modifications and variations can be made to the structure of the present invention without departing from the scope or spirit of the invention. In view of the foregoing, it is intended that the present invention covers modifications and variations of this invention provided they fall within the scope of the following claims and their equivalents.

What is claimed is:

1. A method for forming a photoresist pattern, comprising:
forming a photoresist layer over a substrate;
performing a exposure process and a development process to the photoresist layer to form a patterned photoresist layer; and
performing a multiple-trimming process to the patterned photoresist layer, wherein the multiple-trimming process comprises at least one step of alkaline solution treatment and/or at least one step of neutral solution treatment.

2. The method of claim 1, wherein the multiple-trimming process comprises steps of firstly performing at least one step of the alkaline solution treatment and then performing at least one step of the neutral solution treatment.

3. The method of claim 1, wherein the multiple-trimming process comprises steps of firstly performing at least one step of the neutral solution treatment and then performing at least one step of the alkaline solution treatment.

4. The method of claim 1, wherein the multiple-trimming process comprises consecutively performing two steps of the alkaline solution treatment.

5. The method of claim 1, wherein the multiple-trimming process comprises consecutively performing two steps of the neutral solution treatment.

6. The method of claim 1, wherein the multiple-trimming process comprises alternately performing multiple steps of the neutral solution treatment and multiple steps of the alkaline solution treatment.

7. The method of claim 1, further comprising a heating treatment of 90-150° C. during the multiple-trimming process.

8. The method of claim 1, wherein the alkaline solution used in the step of alkaline solution treatment has a pH value lower than that of a developer used in the development process.

9. The method of claim 1, wherein the alkaline solution comprises an organic alkali.

10. The method of claim 1, wherein the neutral solution is water, a surfactant, or a mixture thereof.

11. The method of claim 10, wherein the surfactant comprises acetylene diol.

12. The method of claim 10, wherein the surfactant has a pH value greater than 5.

13. The method of claim 1, wherein a developer used in the development process comprises an organic alkali.

14. A method for trimming a photoresist pattern, comprising at least one step alkaline solution treatment and/or at least one step of neutral solution treatment to trim the photoresist pattern.

15. The method of claim 14, comprising steps of firstly performing at least one step of the alkaline solution treatment and then performing at least one step of the neutral solution treatment.

16. The method of claim 14, comprising steps of firstly performing at least one step of the neutral solution treatment and then performing at least one step of the alkaline solution treatment.

17. The method of claim 14, wherein the multiple-trimming process comprises consecutively performing two steps of the alkaline solution treatment.

18. The method of claim 14, wherein the multiple-trimming process comprises consecutively performing two steps of the neutral solution treatment.

19. The method of claim 14, comprising alternately performing multiple steps of the neutral solution treatment and multiple steps of the alkaline solution treatment.

20. The method of claim 14, further comprising a heating treatment at 90° C. to 150° C. when the photoresist pattern is being trimmed.

21. The method of claim 14, wherein the alkaline solution comprises an organic alkali.

22. The method of claim 21, wherein the alkaline solution has a pH value between 8 and 14.

23. The method of claim 14, wherein the neutral solution is water, a surfactant, or a mixture of water and a surfactant.

24. The method of claim 23, wherein the surfactant comprises acetylene diol.

25. The method of claim 23, wherein the surfactant has a pH value greater than 5.
